(19) United States
(12) Patent Application Publication
(10) Pub. No.: US 2026/0218597 A1
(43) Pub. Date: Jul. 30, 2026

(54) DRILL BIT DESIGN AND DRILLING OPERATION CONTROL WORKFLOW FOR MITIGATING TORQUE OSCILLATIONS

(71) Applicant: Schlumberger Technology Corporation, Sugar Land, TX (US)

(72) Inventors: Bo Liu, Beijing (CN); Feng Feng, Beijing (CN); Gang Xu, Beijing (CN); Yuelin Shen, Houston, TX (US)

(21) Appl. No.: 19/036,204

(22) Filed: Jan. 24, 2025

(51) Int. Cl. E21B 44/00; E21B 10/00

(52) U.S. Cl. CPC E21B 44/00; E21B 10/00; E21B 2200/20

(57) ABSTRACT

A method including receiving cutter lab test data associated with cutter types; generating a first model based on the cutter lab test data, wherein the first model is representative of effects to one or more rock types provided by using the cutter types; receiving bit lab test data associated with drill bits; generating a second model based on the first model and the bit lab test data, wherein the second model is representative of additional effects to the one or more rock types provided by the drill bits; receiving drilling log data associated with additional drill bits; simulating drilling dynamics for the drill bits and additional drill bits based on the second model and the drilling log data; receiving borehole data associated with a borehole; and determining a bit design for use in the borehole based on the simulated drilling dynamics and the borehole data.

### BACKGROUND

The present disclosure relates generally to a workflow for designing drill bits and controlling drilling operations to mitigate high frequency torsional oscillations (HFTOs).

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

A drill string within a borehole may be used to complete drilling operations. However, HFTOs may apply stress on the drill string that may cause damage to and/or failure of the tools along the drill string. HFTOs may be difficult to identify during operations until the critical failure of the drill string. Formation strength, bit type, and drilling parameters have a direct influence on HFTOs and may be modified to mitigate HFTOs. As such, improved methods for designing drill bits and controlling drilling operations may be useful.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In certain embodiments, a method for designing a drill bit includes receiving cutter lab test data associated with various cutter types; generating a first model based on the cutter lab test data and representative of effects to various rock types provided by using the various cutter types; receiving bit lab test data associated with a first set of various drill bits; generating a second model based on the first model and the bit lab test data and representative of additional effects to the various rock types provided by using one or more drill bits of the first set of drill bits deployed in a bottom hole assembly with one or more cutter types; receiving drilling log data associated with a second set of various drill bits including the one or more drill bits; simulating drilling dynamics for the first set of drill bits and the second set of drill bits based on the second model and the drilling log data; receiving borehole data associated with a borehole; and determining a bit design for use in the borehole based on the simulated drilling dynamics and the borehole data.

### BRIEF DESCRIPTION OF DRAWINGS

These and other features, aspects, and advantages of the present disclosure will become better understood when the following detailed description is read with reference to the accompanying drawings in which like characters represent like parts throughout the drawings, wherein:

FIG. 1 is an example of a system that includes a workspace framework, in accordance with aspects of the present disclosure;

FIG. 2 is an example of a wellsite, in accordance with aspects of the present disclosure;

FIG. 3 is an example of a drill bit suitable for drilling through formation of rock to form a borehole, in accordance with aspects of the present disclosure;

FIG. 4 is an example of a blade that may be part of a drill bit and examples of cutters, in accordance with aspects of the present disclosure;

FIG. 5 is a flowchart of the workflow for simulating drilling dynamics and mitigating HFTOs based on the simulated drilling dynamics, in accordance with aspects of the present disclosure;

FIG. 6 is a plot of the speed-dependent vertical force for a cutter, in accordance with aspects of the present disclosure;

FIG. 7 is a plot of the speed-based torque of a drill bit, in accordance with aspects of the present disclosure;

FIG. 8 is an RPM plot output by a drilling simulator, in accordance with aspects of the present disclosure;

FIG. 9 is a Fast Fourier Transform of the RPM plot of FIG. 8, in accordance with aspects of the present disclosure;

FIG. 10 is a plot of the torque amplitude distribution along a bottom hole assembly, in accordance with aspects of the present disclosure; and

FIG. 11 is a plot of the shear stress along the bottom hole assembly of FIG. 10, in accordance with aspects of the present disclosure.

### DETAILED DESCRIPTION

One or more specific embodiments of the present disclosure will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” “the,” and “said” are intended to mean that there are one or more of the elements. The terms “comprising,” “including,” and “having” are intended to be inclusive and mean that there may be additional elements other than the listed elements. Any examples of operating parameters and/or environmental conditions are not exclusive of other parameters/conditions of the disclosed embodiments.

Certain embodiments commensurate in scope with the present disclosure are summarized below. These embodiments are not intended to limit the scope of the disclosure, but rather these embodiments are intended only to provide a brief summary of certain disclosed embodiments. Indeed, the present disclosure may encompass a variety of forms that may be similar to or different from the embodiments set forth below.

The present disclosure relates to determining drilling parameters to reduce the presence or occurrences of high frequency torsional oscillations (HFTOs) during a drilling operation within a borehole. HFTOs may cause stress on a drill string, particularly the bottom hole assembly (BHA), during drilling operations. This stress may cause damage to and/or failure of the tools in the drill string. Such damage may cause drilling operations to cease while repairs are made to the drill string. Furthermore, because HFTOs do not generally affect the efficiency of drilling operations or the rate of penetration, the presence of HFTOs may go unnoticed until a critical failure of the drill string. However, pre-drilling modifications to the drill bit may mitigate the effect of HFTOs and prevent critical failure of the drill string during drilling operations.

With the foregoing in mind, the present embodiments include drilling design system that may employ different models to determine a suitable design for a drill bit to perform respective drilling operations in a corresponding subsurface region of the earth. By way of example, the drilling design system may employ a speed-dependent cutter-rock interaction model, a bit model, and a drilling dynamics simulator at different stages to determine a suitable drill bit design. After determining the drill bit design, in some embodiments, the drilling design system may determine and adjust drilling parameters of a drill system during drilling operations to reduce the presence of HFTOs.

Keeping the foregoing in mind, the speed-dependent cutter-rock interaction model (hereinafter “the cutter model”) may be created and trained based on single cutter lab testing results. The single cutter lab tests may include testing the force of various cutters of different shapes, sizes, and materials against different types of rock at various speeds. The force and the speed may be used to calculate coefficients of a machine learning algorithm describing a relationship (e.g., effectiveness, integrity of cutter over time) between the cutter and the rock. The drilling design system may analyze the results of the single cutter lab testing to create the cutter model. Additional single cutter lab test results for different instances of the test with the same or different cutters and the same or different types of rock may be added to the cutter model to improve the cutter model's accuracy.

Additionally, the bit model may be created using bit lab tests results and the cutter model. The bit lab tests may include testing the force provided by various drill bits against various types of rocks at various speeds to determine the expected bit torque response. The drilling design system may train the cutter model to match the expected bit torque response. Based on the matched characteristics and training, the drilling design system may create the bit model. In some embodiments, the bit lab tests may also be used to train the bit model. As such, additional bit lab test results may be added to the bit model to improve the bit model's accuracy.

With the foregoing in mind, the drilling simulator may apply the cutter model and the bit model to determine model outputs that may include data and/or graphical representations of parameters affecting HFTOs. For example, the outputs may include a Fast Fourier transform plot where peaks indicate the expected presence of torsional vibrations in a bottom hole assembly (BHA) of a corresponding rock formation. As another example, the outputs may include data or a graphical representation of torque distribution along the BHA. In some embodiments, to further train the drilling dynamics simulator and improve simulator's accuracy, the drilling design system may receive field logs representative of the detected presence of HFTOs on previously performed drilling operations.

In some embodiments, the drilling design system may employ the drilling dynamics simulator before drilling operations to determine the appropriate cutter and drill bit. That is, an operator may provide inputs for the desired speed and the desired rock formation for drilling to the drilling design system. The drilling design system may then analyze various cutter and drill bit designs to drill at a particular speed in a particular rock formation and choose the cutter and drill bit that results in the least HFTOs. In the same way, the drilling design system may employ the drilling dynamics simulator to determine the optimal drilling parameters (e.g., speed of drill bit, weight on bit) for reducing HFTOs. An operator may provide inputs to the drilling design system for the cutter being used, the drill bit being used, and the rock formation being drilled. In turn, the drilling design system may analyze the expected performance, integrity, wear, and effectiveness of the cutter and drill bit drilling through the rock formation at various speeds and weights on bit. The drilling design system may analyze the outputs to determine which speed and/or weight on bit results in the least HFTOs.

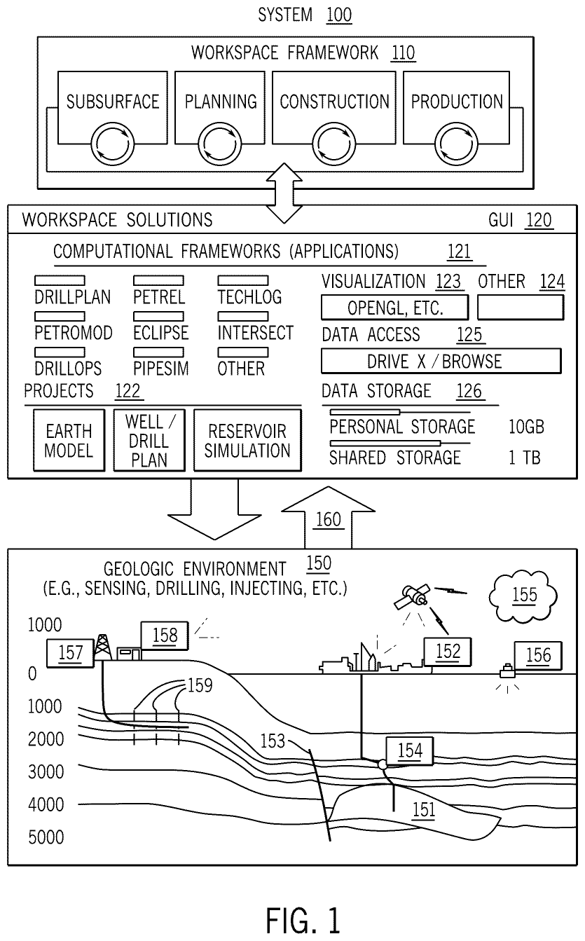

By way of introduction, FIG. 1 shows an example of a system 100 that includes a workspace framework 110 that may provide for instantiation of, rendering of, and/or interactions with a graphical user interface (GUI) 120. In the example of FIG. 1, the GUI 120 may include graphical controls for computational frameworks (e.g., applications) 121, projects 122, visualization features 123, one or more other features 124, data access 125, and data storage 126.

In the example of FIG. 1, the workspace framework 110 may be tailored to a particular geologic environment such as an example geologic environment 150. For example, the geologic environment 150 may include layers (e.g., stratification) that include a reservoir 151 and that may be intersected by a fault 153. As an example, the geologic environment 150 may be outfitted with a variety of sensors, detectors, actuators, and the like. For example, equipment 152 may include communication circuitry to receive and to transmit information with respect to one or more networks 155. Such information may include information associated with downhole equipment 154, which may be equipment to acquire information, to assist with resource recovery, and the like. Other equipment 156 may be located remote from a wellsite and include sensing, detecting, emitting, or other circuitry. Such equipment may include storage and communication circuitry to store and to communicate data, instructions, and the like. As an example, one or more satellites may be provided for purposes of communications, data acquisition, and the like. For example, FIG. 1 shows a satellite in communication with the network 155 that may be configured for communications, noting that the satellite may additionally or alternatively include circuitry for imagery (e.g., spatial, spectral, temporal, radiometric).

FIG. 1 also shows the geologic environment 150 as optionally including equipment 157 and 158 associated with a well that includes a substantially horizontal portion that may intersect with one or more fractures 159. For example, consider a well in a shale formation that may include natural fractures, artificial fractures (e.g., hydraulic fractures) or a combination of natural and artificial fractures. As an example, a well may be drilled for a reservoir that is laterally extensive. In such an example, lateral variations in properties, stresses, etc. may exist where an assessment of such variations may assist with planning, operations, etc. to develop a laterally extensive reservoir (e.g., via fracturing, injecting, extracting). As an example, the equipment 157 and/or 158 may include components and/or systems for fracturing, seismic sensing, analysis of seismic data, assessment of one or more fractures, and the like.

In the example of FIG. 1, the GUI 120 shows some examples of computational frameworks, including the DRILLPLAN, DRILLOPS, PETREL, TECHLOG, PETROMOD, ECLIPSE, PIPESIM, and INTERSECT frameworks (SLB, Houston, Texas).

The DRILLPLAN framework provides for digital well construction planning and includes features for automation of repetitive tasks and validation workflows, enabling improved quality drilling programs (e.g., digital drilling plans) to be produced quickly with assured coherency.

The DRILLOPS framework may execute a digital drilling plan and ensure plan adherence, while delivering goal-based automation. The DRILLOPS framework may generate activity plans automatically and individual operations, whether they are monitored and/or controlled on the rig or in town. Automation may utilize data analysis and learning systems to assist and optimize tasks, such as, for example, setting ROP to drilling a stand. A preset menu of automatable drilling tasks may be rendered, and, using data analysis and models, a plan may be executed in a manner to achieve a specified goal, where, for example, measurements may be utilized for calibration. The DRILLOPS framework provides flexibility to modify and replan activities dynamically, for example, based on a live appraisal of various factors (e.g., equipment, personnel, and supplies). Well construction activities (e.g., tripping, drilling, cementing) may be continually monitored and dynamically updated using feedback from operational activities. The DRILLOPS framework may provide for various levels of automation based on planning and/or re-planning (e.g., via the DRILLPLAN framework), feedback, and the like.

The PETREL framework may be part of the DELFI environment for utilization in geosciences and geoengineering, for example, to analyze subsurface data from exploration to production of fluid from a reservoir. The DELFI cognitive exploration and production (E&P) environment (SLB, Houston, Texas), referred to herein as the DELFI environment or DELFI framework, is a secure, cognitive, cloud-based collaborative environment that integrates data and workflows with digital technologies, such as artificial intelligence and machine learning.

The PETREL framework provides components that allow for optimization of various exploration, development and production operations. The PETREL framework includes seismic to simulation software components that may output information for use in increasing reservoir performance, for example, by improving asset team productivity. Through use of such a framework, various professionals (e.g., geophysicists, geologists, and reservoir engineers) may develop collaborative workflows and integrate operations to streamline processes (e.g., with respect to one or more geologic environments, etc.). Such a framework may be considered an application (e.g., executable using one or more devices) and may be considered a data-driven application (e.g., where data is input for purposes of modeling, simulating, etc.).

The TECHLOG framework may handle and process field and laboratory data for a variety of geologic environments (e.g., deepwater exploration, shale). The TECHLOG framework may structure wellbore data for analyses, planning, and the like.

The PETROMOD framework provides petroleum systems modeling capabilities that may combine one or more of seismic, well, and geological information to model the evolution of a sedimentary basin. The PETROMOD framework may predict if, and how, a reservoir has been charged with hydrocarbons, including the source and timing of hydrocarbon generation, migration routes, quantities, and hydrocarbon type in the subsurface or at surface conditions.

The ECLIPSE framework provides a reservoir simulator (e.g., as a computational framework) with numerical solutions for fast and accurate prediction of dynamic behavior for various types of reservoirs and development schemes.

The INTERSECT framework provides a high-resolution reservoir simulator for simulation of detailed geological features and quantification of uncertainties, for example, by creating accurate production scenarios and, with the integration of precise models of the surface facilities and field operations, the INTERSECT framework may produce reliable results, which may be continuously updated by real-time data exchanges (e.g., from one or more types of data acquisition equipment in the field that may acquire data during one or more types of field operations). The INTERSECT framework may provide completion configurations for complex wells where such configurations may be built in the field, may provide detailed enhanced-oil-recovery (EOR) formulations where such formulations may be implemented in the field, may analyze application of steam injection and other thermal EOR techniques for implementation in the field, advanced production controls in terms of reservoir coupling and flexible field management, and flexibility to script customized solutions for improved modeling and field management control. The INTERSECT framework, as with the other example frameworks, may be utilized as part of the DELFI environment, for example, for rapid simulation of multiple concurrent cases. For example, a workflow may utilize one or more of the DELFI environment on demand reservoir simulation features.

Additional computational frameworks made be provided. For example, an additional framework may provide a drilling simulator (e.g., as a computational framework) for simulating the effect of various types of drill bits and operating parameters on HFTOs when drilling various rock formations.

The aforementioned DELFI environment provides various features for workflows as to subsurface analysis, planning, construction and production, for example, as illustrated in the workspace framework 110. As shown in FIG. 1, outputs from the workspace framework 110 may be utilized for directing or controlling one or more processes in the geologic environment 150 and, feedback 160 may be received via one or more interfaces in one or more forms (e.g., acquired data as to operational conditions, equipment conditions, environment conditions). As an example, a workflow may progress to a geology and geophysics (G&G) service provider, which may generate a well trajectory, which may involve execution of one or more G&G frameworks (e.g., consider the PETREL framework, etc.).

In the example of FIG. 1, the visualization features 123 may be implemented via the workspace framework 110, for example, to perform tasks associated with one or more of subsurface regions, planning operations, constructing wells and/or surface fluid networks, and producing from a reservoir.

As an example, a visualization process may implement one or more of various features that may be suitable for one or more web applications. For example, a template may involve use of the JAVASCRIPT object notation format (JSON) and/or one or more other languages/formats. As an example, a framework may include one or more converters. For example, consider a JSON to PYTHON converter and/or a PYTHON to JSON converter. Such an approach may provide for compatibility of devices and/or frameworks with respect to one or more sets of instructions.

As an example, visualization features may provide for visualization of various earth models, properties, and the like in one or more dimensions. As an example, visualization features may provide for rendering of information in multiple dimensions, which may optionally include multiple resolution rendering. In such an example, information being rendered may be associated with one or more frameworks and/or one or more data stores. As an example, visualization features may include one or more control features for control of equipment, which may include, for example, field equipment that may perform one or more field operations. As an example, a workflow may utilize one or more frameworks to generate information that may be utilized to control one or more types of field equipment (e.g., drilling equipment, wireline equipment, fracturing equipment).

As to a model that may be suitable for utilization by a drilling simulator, consider acquisition of data as acquired during drilling operations. As an example, drilling operations may provide data regarding the torque, stress, vibrations, or any combination thereof on the drill bit. The data may be processed and interpreted, for example, to determine which drill bit designs, speeds of the drill bit, and weights on bit mitigate HFTOs.

While several simulators are illustrated in the example of FIG. 1, one or more other simulators may be utilized, additionally or alternatively. For example, consider the VISAGE geomechanics simulator (SLB, Houston Texas) or the PIPESIM network simulator (SLB, Houston Texas).

As an example, a workflow may utilize one or more types of data for one or more processes (e.g., stratigraphic modeling, basin modeling, completion designs, drilling, production, injection). As an example, one or more tools may provide data that may be used in a workflow or workflows that may implement one or more frameworks (e.g., PETREL, TECHLOG, PETROMOD, ECLIPSE).

In the example of FIG. 1, drilling may be performed in the geologic environment 150, for example, to access the reservoir 151, which may be accessed from land or offshore. In FIG. 1, the downhole equipment 154 may be, for example, part of a bottom hole assembly (BHA). The BHA may be used to drill a well. The downhole equipment 154 may communicate information to equipment at the surface and may receive instructions and information from the equipment at the surface. During a well construction process, a variety of operations (such as cementing, wireline evaluation, testing) may be conducted. In such embodiments, data collected by tools and sensors and used for reasons such as reservoir characterization may be collected and transmitted.

A well may include a substantially horizontal portion (e.g., lateral portion) that may intersect with one or more fractures. For example, a well in a shale formation may pass through natural fractures, artificial fractures (e.g., hydraulic fractures), or a combination thereof. Such a well may be constructed using directional drilling techniques as described herein. However, these same techniques may be used in connection with other types of directional wells (such as slant wells, S-shaped wells, deep inclined wells, and others) and are not limited to horizontal wells.

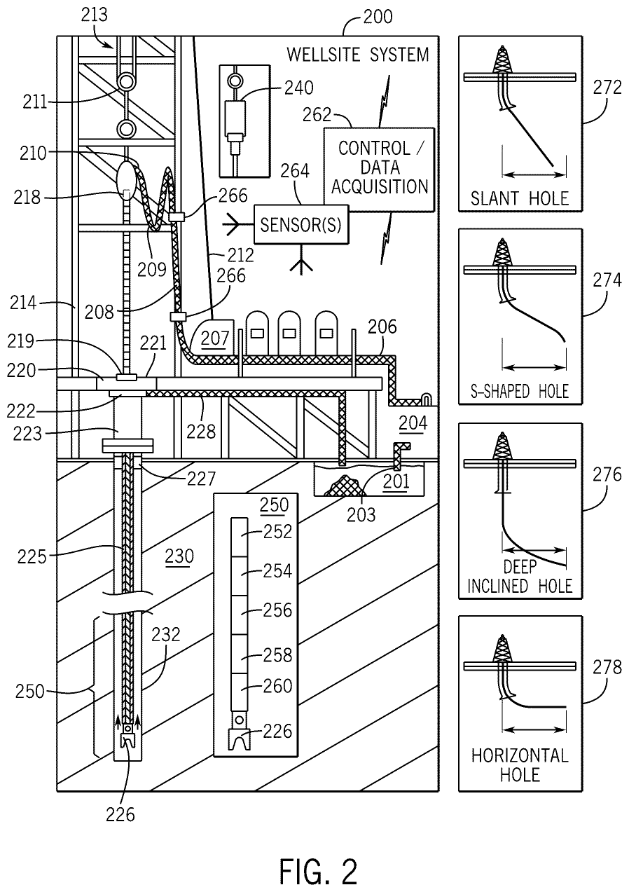

FIG. 2 shows an example of a wellsite system 200 (e.g., at a wellsite that may be onshore or offshore). As shown, the wellsite system 200 may include a mud tank 201 for holding mud and other material (e.g., where mud may be a drilling fluid), a suction line 203 that serves as an inlet to a mud pump 204 for pumping mud from the mud tank 201 such that mud flows to a vibrating hose 206, a drawworks 207 for winching drill line or drill lines 212, a standpipe 208 that receives mud from the vibrating hose 206, a kelly hose 209 that receives mud from the standpipe 208, a gooseneck or goosenecks 210, a traveling block 211, a crown block 213 for carrying the traveling block 211 via the drill line or drill lines 212, a derrick 214, a kelly 218 or a top drive 240, a kelly drive bushing 219, a rotary table 220, a drill floor 221, a bell nipple 222, one or more blowout preventors (BOPs) 223, a drill string 225, a drill bit 226, a casing head 227 and a flow pipe 228 that carries mud and other material to, for example, the mud tank 201.

In the example system of FIG. 2, a borehole 232 is formed in subsurface formations 230 by rotary drilling. The wellsite system may additionally and/or alternatively use directional drilling.

As shown in the example of FIG. 2, the drill string 225 is suspended within the borehole 232 and has a drill string assembly 250 that includes the drill bit 226 at its lower end. As an example, the drill string assembly 250 may be a bottom hole assembly (BHA).

The wellsite system 200 may provide for operation of the drill string 225 and other operations. As shown, the wellsite system 200 includes the platform and the derrick 214 positioned over the borehole 232. As mentioned, the wellsite system 200 may include the rotary table 220 where the drill string 225 pass through an opening in the rotary table 220.

As shown in the example of FIG. 2, the wellsite system 200 may include the kelly 218 and associated components or a top drive 240 and associated components. As to a kelly, the kelly 218 may be a square or hexagonal metal/alloy bar with a hole drilled therein that serves as a mud flow path. The kelly 218 may be used to transmit rotary motion from the rotary table 220 via the kelly drive bushing 219 to the drill string 225, while allowing the drill string 225 to be lowered or raised during rotation. The kelly 218 may pass through the kelly drive bushing 219, which may be driven by the rotary table 220. As an example, the rotary table 220 may include a master bushing that operatively couples to the kelly drive bushing 219 such that rotation of the rotary table 220 may turn the kelly drive bushing 219 and hence the kelly 218. The kelly drive bushing 219 may include an inside profile matching an outside profile (e.g., square, hexagonal) of the kelly 218; however, with slightly larger dimensions so that the kelly 218 may freely move up and down inside the kelly drive bushing 219.

As to a top drive, the top drive 240 may provide functions performed by a kelly and a rotary table. The top drive 240 may turn the drill string 225. As an example, the top drive 240 may include one or more motors (e.g., electric and/or hydraulic) connected with appropriate gearing to a short section of pipe called a quill, that in turn may be screwed into a saver sub or the drill string 225 itself. The top drive 240 may be suspended from the traveling block 211, so the rotary mechanism is free to travel up and down the derrick 214. As an example, a top drive 240 may allow for drilling to be performed with more joint stands than a kelly/rotary table approach.

In the example of FIG. 2, the mud tank 201 may hold mud, which may be one or more types of drilling fluids. As an example, a wellbore may be drilled to produce fluid, inject fluid or both (e.g., hydrocarbons, minerals, water).

In the example of FIG. 2, the drill string 225 (e.g., including one or more downhole tools) may be composed of a series of pipes coupled together to form a long tube with the drill bit 226 at the lower end thereof. As the drill string 225 is advanced into a wellbore for drilling, at some point in time prior to or coincident with drilling, the mud may be pumped by the pump 204 from the mud tank 201 (e.g., or other source) via the lines (e.g., hoses, standpiepes) 206, 208 and 209 to a port of the kelly 218 or, for example, to a port of the top drive 240. The mud may then flow via passage(s) in the drill string 225 and out of ports located on the drill bit 226 (see, e.g., a directional arrow). As the mud exits the drill string 225 via ports in the drill bit 226, it may then circulate upwardly through an annular region between an outer surface(s) of the drill string 225 and surrounding wall(s) (e.g., open borehole, casing), as indicated by directional arrows. In such a manner, the mud lubricates the drill bit 226 and carries heat energy (e.g., frictional or other energy) and formation cuttings to the surface where the mud and/or cuttings may be returned to the mud tank 201, for example, for recirculation (e.g., with processing to remove cuttings).

The mud pumped by the pump 204 into the drill string 225 may, after exiting the drill string 225, form a mudcake that lines the wellbore which, among other functions, may reduce friction between the drill string 225 and surrounding wall(s) (e.g., borehole, casing). A reduction in friction may facilitate advancing or retracting the drill string 225. During a drilling operation, the entire drill string 225 may be pulled from a wellbore and optionally replaced, for example, with a new or sharpened drill bit, a smaller diameter drill string, etc. As mentioned, the act of pulling a drill string out of a hole or replacing it in a hole is referred to as tripping. A trip may be referred to as an upward trip or an outward trip or as a downward trip or an inward trip depending on trip direction.

As an example, consider a downward trip where upon arrival of the drill bit 226 of the drill string 225 at a bottom of a wellbore, pumping of the mud commences to lubricate the drill bit 226 for purposes of drilling to enlarge the wellbore. As mentioned, the mud may be pumped by the pump 204 into a passage of the drill string 225 and, upon filling of the passage, the mud may be used as a transmission medium to transmit energy, for example, energy that may encode information as in mud-pulse telemetry.

As an example, mud-pulse telemetry equipment may include a downhole device configured to effect changes in pressure in the mud to create an acoustic wave or waves upon which information may modulated. In such an example, information from downhole equipment (e.g., one or more modules of the drill string 225) may be transmitted uphole to an uphole device, which may relay such information to other equipment for processing and control.

As an example, telemetry equipment may operate via transmission of energy via the drill string 225 itself. For example, consider a signal generator that imparts coded energy signals to the drill string 225 and repeaters that may receive such energy and repeat it to further transmit the coded energy signals.

As an example, the drill string 225 may be fitted with telemetry equipment 252 that includes a rotatable drive shaft, a turbine impeller mechanically coupled to the drive shaft such that the mud may cause the turbine impeller to rotate, a modulator rotor mechanically coupled to the drive shaft such that rotation of the turbine impeller causes said modulator rotor to rotate, a modulator stator mounted adjacent to or proximate to the modulator rotor such that rotation of the modulator rotor relative to the modulator stator creates pressure pulses in the mud, and a controllable brake for selectively braking rotation of the modulator rotor to modulate pressure pulses. In such example, an alternator may be coupled to the aforementioned drive shaft where the alternator includes at least one stator winding electrically coupled to a control circuit to selectively short the at least one stator winding to electromagnetically brake the alternator and thereby selectively brake rotation of the modulator rotor to modulate the pressure pulses in the mud.

In the example of FIG. 2, a control/data acquisition system 262 may include circuitry to sense pressure pulses generated by telemetry equipment 252 and, for example, communicate sensed pressure pulses or information derived therefrom for process and control. With this in mind, the control/data acquisition system 262 may include a number of components to perform the various operations described herein. For example, the control/data acquisition system 262 may include a communication component, processing units, a memory, a storage, input/output (IO) ports, a display, and the like. The communication component may be a wireless or wired communication component that facilitates communication between the multi-tenant queuing system, the client systems, and any other suitable electronic device.

Each of the processing units may include multiple processor devices that may be of any type of computer processor or microprocessor capable of executing computer-executable code. Each processing unit may also include multiple processors that may perform the operations described below. The processing units may perform or execute tasks provided by a drilling design system. That is, the drilling design system may include limited processing capabilities, software applications, or the like and may employ the control/data acquisition system 262 to supplement those limitations. Additional details with regard to the control/data acquisition system 262 efficiently performing or executing tasks provided by the drilling design system will be discussed below.

The memory and the storage may be any suitable article of manufacture that may serve as media to store processor-executable code, data, or the like. These articles of manufacture may represent computer-readable media (i.e., any suitable form of memory or storage) that may store the processor-executable code used by the processing units to perform the presently disclosed techniques. The memory and the storage may represent non-transitory computer-readable media (e.g., any suitable form of memory or storage) that may store the processor-executable code used by the processing units to perform various techniques described herein. It should be noted that non-transitory merely indicates that the media is tangible and not a signal.

The IO ports may couple to the drilling design system, one or more input devices, one or more displays, or the like to facilitate human or machine interaction with the control/data acquisition system 262. The display may operate to depict visualizations associated with software or executable code being processed by the processing units. In one embodiment, the display may be a touch display capable of receiving inputs from an operator of the control/data acquisition system 262. The display may be any suitable type of display, such as a liquid crystal display (LCD), plasma display, or an organic light emitting diode (OLED) display, for example. Additionally, in one embodiment, the display may be provided in conjunction with a touch-sensitive mechanism (e.g., a touch screen) that may function as part of a control interface for the control/data acquisition system 262.

Although the components of the control/data acquisition system 262 are described with respect to the control/data acquisition system 262, it should be noted that any other computing or processing device described herein may also include the same or similar components to perform, or facilitate performing, the various operations described herein. Moreover, it should be understood that the components described above are exemplary figures and the control/data acquisition system 262 and other suitable computing systems may include additional or fewer components as detailed above.

The assembly 250 of the illustrated example includes a logging-while-drilling (LWD) module 254 (e.g., a LWD tool), a measuring-while-drilling (MWD) module 256 (e.g., a MWD tool), an optional module 258, a rotary steerable system (RSS), an at-bit steerable system (ABSS), and/or a motor 260, and the drill bit 226. Such components or modules may be referred to as tools where a drill string 225 may include a plurality of tools.

As an example, an RSS may provide for directional drilling with continuous rotation from the surface, for example, without having to utilize a slide mode (e.g., sliding mode using a mud motor). An RSS may be deployed when drilling directional, horizontal, and/or extended-reach wells. As an example, an RSS may provide for applying a relatively consistent side force (e.g., akin to a stabilizer) that rotates with a drill string 225 or otherwise orients a drill bit in a desired direction while continuously rotating at the same number of rotations per minute as the drill string 225.

As an example, an ABSS may be a type of RSS. As an example, an ABSS may include a steering sleeve assembly. For example, consider a sleeve assembly that may include one or more features of an ABSS such as the NEOSTEER system (SLB, Houston, Texas). As an example, an ABSS may include an actuating system that may controllably exert pressure against a borehole wall. For example, consider a number of integrated pistons that may provide for enhancing curvature leverage within a cutting structure. In such an example, such leveraging may provide for achieving desirable build rates. An ABSS may provide for meeting curvature requirements in a curve section and directional control in a lateral section. As an example, a steering unit may incorporate metal-to-metal hydraulic seals that may help to minimize erosion and enhance hydraulic design capacity for improved performance. As an example, an ABSS may be configured within a motor-assisted BHA to provide suitable RPM levels accompanied by directional control and reliable steerability.

As an example, directional drilling may involve use of a mud motor; however, in various scenarios, a mud motor may present some challenges depending on factors such as rate of penetration (ROP) and transferring weight to a drill bit (e.g., weight on bit, WOB) due to friction. A mud motor may be a positive displacement motor (PDM) that operates to drive a drill bit (e.g., during directional drilling). A PDM operates as drilling fluid is pumped through it where the PDM converts hydraulic power of the drilling fluid into mechanical power to cause the drill bit to rotate.

As explained, one or more technologies may be utilized for directional drilling. Directional drilling involves drilling into the Earth to form a deviated bore such that the trajectory of the bore is not vertical; rather, the trajectory deviates from vertical along one or more portions of the bore. As an example, consider a target that is located at a lateral distance from a surface location where a rig may be stationed. In such an example, drilling may commence with a vertical portion and then deviate from vertical such that the bore is aimed at the target and, eventually, reaches the target. Directional drilling may be implemented where a target may be inaccessible from a vertical location at the surface of the Earth, where material exists in the Earth that may impede drilling or otherwise be detrimental (e.g., consider a salt dome), where a formation is laterally extensive (e.g., consider a relatively thin yet laterally extensive reservoir), where multiple bores are to be drilled from a single surface bore, where a relief well is desired, and the like.

In the example of FIG. 2, the LWD module 254 may be housed in a suitable type of drill collar and may contain one or a plurality of selected types of logging tools. It will also be understood that more than one LWD and/or MWD module may be employed. Where the position of a module is mentioned, as an example, it may refer to a module at the position of the LWD module 254, the MWD module 256, etc. An LWD module may include capabilities for measuring, processing, and storing information, as well as for communicating with the surface equipment. In the illustrated example, the LWD module 254 may include a seismic measuring device.

In the example of FIG. 2, the MWD module 256 may be housed in a suitable type of drill collar and may contain one or more devices for measuring characteristics of the drill string 225 and the drill bit 226. As an example, the MWD module 256 may include equipment for generating electrical power, for example, to power various components of the drill string 225. As an example, the MWD module 256 may include the telemetry equipment 252, for example, where the turbine impeller may generate power by flow of the mud; it being understood that other power and/or battery systems may be employed for purposes of powering various components. As an example, the MWD module 256 may include one or more of the following types of measuring devices: a weight-on-bit measuring device, a torque measuring device, a vibration measuring device, a shock measuring device, a stick slip measuring device, a direction measuring device, and an inclination measuring device.

FIG. 2 also shows some examples of types of holes that may be drilled. For example, consider a slant hole 272, an S-shaped hole 274, a deep inclined hole 276, and a horizontal hole 278. As an example, a directional well may include several shapes where each of the shapes may aim to meet particular operational demands. As an example, a drilling process may be performed on the basis of information as and when it is relayed to a drilling engineer. As an example, inclination and/or direction may be modified based on information received during a drilling process. As an example, deviation of a bore may be accomplished in part by use of one or more of an RSS, a downhole motor and/or a turbine. As to a motor, for example, a drill string 225 may include a positive displacement motor (PDM).

As an example, a system may be a steerable system and include equipment to perform a method such as geosteering. As an example, a steerable system may include a PDM or a turbine on a lower part of a drill string 225 which, just above a drill bit, a bent sub may be mounted. As an example, above a PDM, MWD equipment that provides real time or near real time data of interest (e.g., inclination, direction, pressure, temperature, real weight on the drill bit, torque stress) and/or LWD equipment may be installed. As to the latter, LWD equipment may make it possible to send to the surface various types of data of interest, including for example, geological data (e.g., gamma ray log, resistivity, density and sonic logs).

The coupling of sensors providing information on the course of a well trajectory, in real time or near real time, with, for example, one or more logs characterizing the formations from a geological viewpoint, may allow for implementing a geosteering method. Such a method may include navigating a subsurface environment, for example, to follow a desired route to reach a desired target or targets.

As an example, a drill string 225 may include an azimuthal density neutron (ADN) tool for measuring density and porosity; a MWD tool for measuring inclination, azimuth and shocks; a compensated dual resistivity (CDR) tool for measuring resistivity and gamma ray related phenomena; one or more variable gauge stabilizers; one or more bend joints; and a geosteering tool, which may include a motor and optionally equipment for measuring and/or responding to one or more of inclination, resistivity and gamma ray related phenomena.

As an example, geosteering may include intentional directional control of a wellbore based on results of downhole geological logging measurements in a manner that aims to keep a directional wellbore within a desired region or zone (e.g., a pay zone). As an example, geosteering may include directing a wellbore to keep the wellbore in a particular section of a reservoir, for example, to minimize gas and/or water breakthrough and, for example, to maximize economic production from a well that includes the wellbore.

Referring again to FIG. 2, the wellsite system 200 may include one or more sensors 264 that are operatively coupled to the control/data acquisition system 262. As an example, a sensor or sensors may be at surface locations. As an example, a sensor or sensors may be at downhole locations. As an example, a sensor or sensors may be at one or more remote locations that are not within a distance of the order of about one hundred meters from the wellsite system 200. As an example, a sensor or sensor may be at an offset wellsite where the wellsite system 200 and the offset wellsite are in a common field (e.g., oil and/or gas field). As another example, one or more of the sensors 264 may be provided for tracking pipe, tracking movement of at least a portion of a drill string 225, and the like.

As an example, the system 200 may include one or more sensors 266 that may sense and/or transmit signals to a fluid conduit such as a drilling fluid conduit (e.g., a drilling mud conduit). For example, in the system 200, the one or more sensors 266 may be operatively coupled to portions of the standpipe 208 through which mud flows. As an example, a downhole tool may generate pulses that may travel through the mud and be sensed by one or more of the one or more sensors 266. In such an example, the downhole tool may include associated circuitry such as, for example, encoding circuitry that may encode signals, for example, to reduce demands as to transmission. As an example, circuitry at the surface may include decoding circuitry to decode encoded information transmitted at least in part via mud-pulse telemetry. As an example, circuitry at the surface may include encoder circuitry and/or decoder circuitry and circuitry downhole may include encoder circuitry and/or decoder circuitry. As an example, the system 200 may include a transmitter that may generate signals that may be transmitted downhole via mud (e.g., drilling fluid) as a transmission medium.

Various types of data associated with field operations may be 1-D series data. For example, consider data as to one or more of a drilling system, downhole states, formation attributes, and surface mechanics being measured as single or multi-channel time series data.

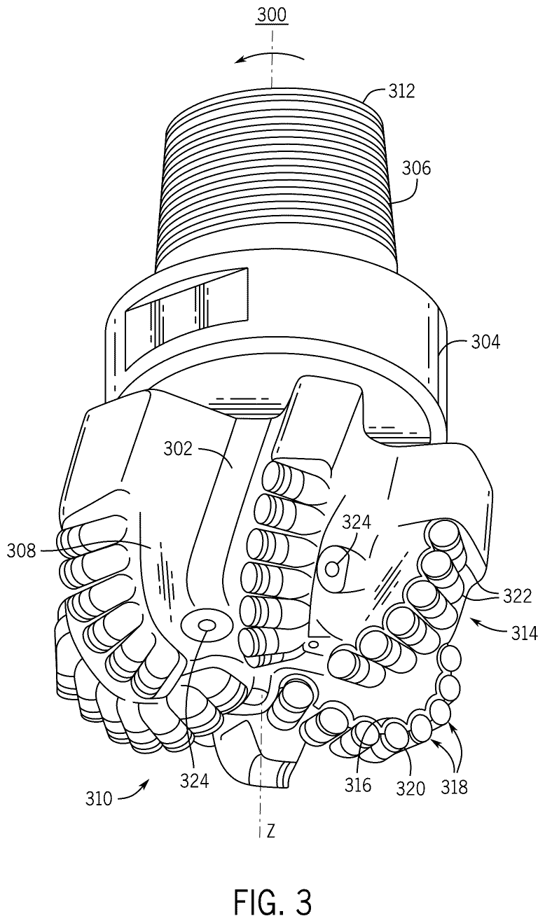

FIG. 3 shows an example of a drill bit 300 suitable for drilling through formations of rock to form a borehole. The drill bit 300 may include a bit body 302, a shank 304, and a threaded connection or pin 306 for connecting the drill bit 300 to a drill string 225 employed to rotate the drill bit 300 to drill a borehole. A bit face 308 may support a cutting structure 310 and be formed on an end of the drill bit 300 that is opposite pin end 312. The drill bit 300 may further be defined according to a central axis z about which drill bit 300 may rotate in a cutting direction represented by arrow.

As shown, the cutting structure 310 may be provided on the face 308 of drill bit 300. The cutting structure 310 may include angularly spaced-apart blades 314 that extend from the bit face 308. While six blades 314 are shown, the number of blades and blade types may vary (e.g., consider more or less blades, primary blades, secondary blades). As an example, a secondary blade of a drill bit may refer to a blade that begins at some distance from a drill bit axis and extends generally radially along a bit face to a periphery of the drill bit.

As an example, a blade may include a blade top 316 for mounting cutting elements 318. Each of the cutting elements 318 may include a respective cutting face 320. As an example, the blades 314 may include pockets 322 where each of the cutting elements 318 may be mounted in a correspond one of the pockets 322 as formed in blade tops 316. The cutting elements 318 may be arranged adjacent one another in a radially extending row proximal a leading edge of each of the blades 314.

As explained, the cutting elements 318 may be embedded in the pockets 322 of the blades 314 where the cutting elements 318 may break rock as the drill bit 300 is rotated on a bottom surface of a borehole. As explained, the cutting elements 318 may be fixed cutter elements that may include PDC or other specially manufactured cutter material.

As an example, the cutting elements 318 may be rotatable cutter elements (e.g., rotatable cutters). For example, a cutting element may include a sleeve portion where a cutting face portion is coupled to a shaft portion received by a bore of the sleeve portion. As an example, one or more cutting elements of the ENDURO 360 family of cutting elements may be utilized (SLB, Houston, Texas). A rotatable cutter may provide for reduction of mechanical and/or thermal effects that may promote wear and/or chipping of a cutter. For example, a fixed cutter is set within a pocket in a manner whereby the fixed cutter does not rotate such that a particular portion of the fixed cutter may engage a formation and wear and/or chip due to mechanical and/or thermal effects. A rotatable cutter may increase durability by helping to ensure that a portion of the rotatable cutter such as an edge that makes contact with a formation is continually refreshed such that the edge may stay sharper longer. As to an edge, consider a perimeter of a cutting face that may be substantially circular and able to rotate by 360 degrees about a longitudinal axis of a rotatable cutter such that the entire perimeter may be available at times to contact rock and break the rock during drilling. As an example, rotating action of a rotatable cutter may improve thermal dissipation, which may help to reduce concentrated heat buildup. Heat buildup may occur in an asymmetric manner, which may cause heterogeneity in temperature distributions within a cutter. As a cutter may be characterized at least in part by thermal properties (e.g., thermal conductivity, coefficient of expansion), heterogeneity in temperature may increase stress or impact stress handling ability of a cutter. By rotating a cutter, heat energy caused by a portion of a cutter being a main portion interacting with rock may be dissipated as that portion rotates to a position where its interaction with rock is reduced and where another portion of the cutter rotates to become the main portion interaction with rock.

As an example, a cutter may be characterized by various dimensions such as, for example, a face dimension. As an example, a face dimension may be a diameter of a cylindrical cutter. For example, consider a diameter in a range from approximately 3 mm to approximately 30 mm or more. As to the ENDURO 360 (e.g., ENDUROBLADE 360) cutter elements, consider sizes of 13 mm, 16 mm, 19 mm, etc. As explained, a rotatable cutter may provide for increased strength and durability, which may provide for increases in run length and/or penetration rate (e.g., ROP).

As an example, a drill bit may include a number of cutters where the cutters may include fixed cutters and/or rotatable cutters. As an example, number, type and/or placement of cutters may be selected to provide desired drill bit behavior, such as, for example, improved durability in one or more high-wear areas of a drill bit.

As explained, drilling fluid (e.g., mud) may flow through passages of a drill bit to help lubricate the drill bit and to carry away cuttings. In the example of FIG. 3, the drill bit 300 is shown as including various openings 324, which may be referred to as mud ports.

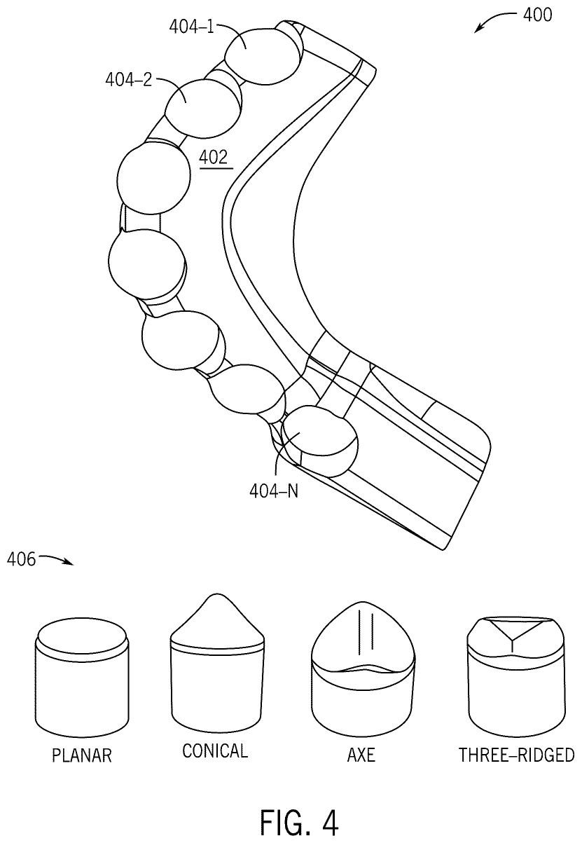

FIG. 4 shows a perspective view of an example of a blade 400 that may be part of a drill bit where the blade 400 includes a blade top 402 with a number of pockets 404-1, 404-2, . . . , 404-N. While the blade 400 includes seven pockets in the illustrated embodiment, a blade may include a lesser or a greater number of pockets.

As an example, one or more types of cutters may be utilized. For example, consider an assembly process that includes selecting one or more types of cutters and seating cutters of selected type or types in pockets of a blade. FIG. 4 shows some examples of cutters 406, which may include a planar cutter, a conical cutter, an axe cutter, a three-ridged cutter, etc. As shown, a cutter may be designed with a particular shape where the cutter and rock interactions may depend at least in part on shape.

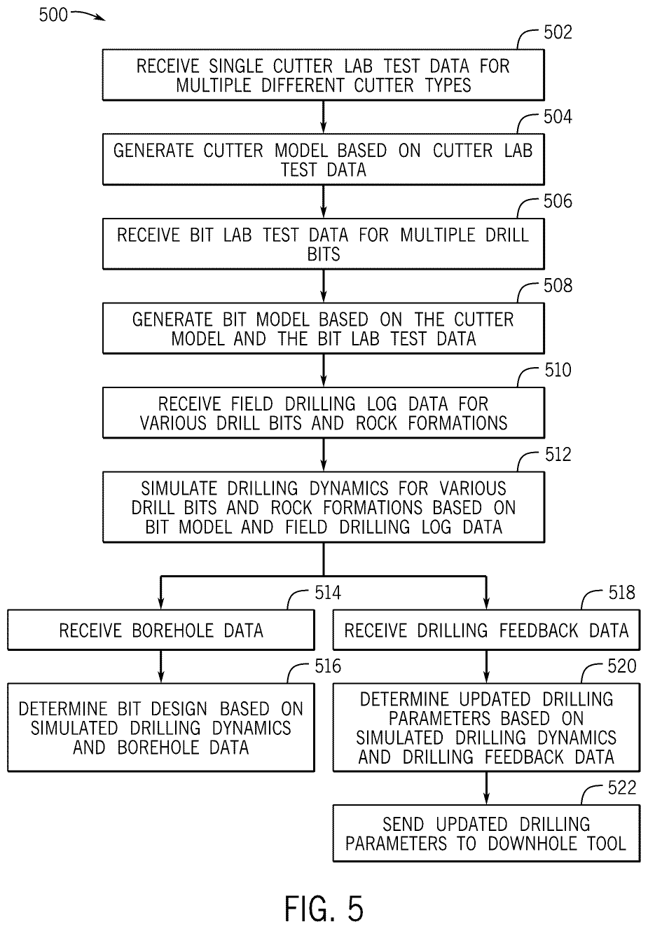

With the foregoing in mind, different types of cutters, drill bits, and drilling dynamics may influence the levels of HFTOs that may be experienced by the drill string 225. FIG. 5 is a flowchart of the workflow 500 for simulating drilling dynamics and mitigating HFTOs based on simulated drilling dynamics. The workflow 500 may be implemented via the control/data acquisition system 262 in the present embodiment. However, the workflow 500 may be implemented on any suitable computing system and/or processor. Although the workflow 500 is described in a particular order, it should be understood that the workflow 500 may be implemented in any suitable order. By way of operation, the workflow 500 may employ a cutter model, a bit model, a drilling simulator, and the like to determine a suitable design for a drill bit to perform drilling operations for a particular borehole and to mitigate HFTOs. The workflow 500 may further include using the models to determine and adjust the drilling parameters of a drill system during drilling operations to reduce the presence of HFTOs.

Referring now to FIG. 5, at block 502, the control/data acquisition system 262 may receive single cutter lab test data for multiple different cutter types. The cutter lab test data may be acquired via one or more laboratory tests. Each laboratory test may include testing a force of a cutter against a rock sample at a number of different speeds. Each laboratory test may be controlled with respect to different parameters, such as angle, force, speed, and the like. Each laboratory test may be repeated for each of the cutter types across different rock types. The cutter types may include cutters of different shapes, sizes, materials, and the like. In some embodiments, the laboratory test may measure a depth, back rake (BR), side rake (SR), roll, or other features created by the cutters across the different rock types.

With the foregoing in mind, the cutter lab test data may also include the data related to the laboratory tests and/or the interactions between the cutter and a rock sample, including the cutter types, the rock types, the controlled variables, any measured values, and other parameters related to the tests. In some embodiments, the cutter lab test data may further include a rock file associated with each of the rock types. The rock file for each of the plurality of rock types may include properties of the rock type such as tortuosity, damping coefficients, friction dependence on speed, and the like.

At block 504, the control/data acquisition system 262 may generate a speed-dependent cutter-rock interaction model (“the cutter model”) based on the cutter lab test data. Additionally, in some embodiments, the control/data acquisition system 262 may train a previously generated cutter model based on additional cutter lab test data to further improve the previously generated cutter model's accuracy.

In some embodiments, the control/data acquisition system 262 may calculate various parameters related to the interaction between the cutter and the rock sample that may be applied by the cutter model. For example, the control/data acquisition system 262 may use the measured values and rock files to determine the vertical force, the cutting force, the side force, or any combination thereof of the cutter against the rock sample. As another example, the control/data acquisition system 262 may generate a friction profile with respect to the speed of the cutter where the friction profile may include a breakaway friction, a Stribeck friction, a Coulomb friction, a stiction friction, a viscous friction, and the like.

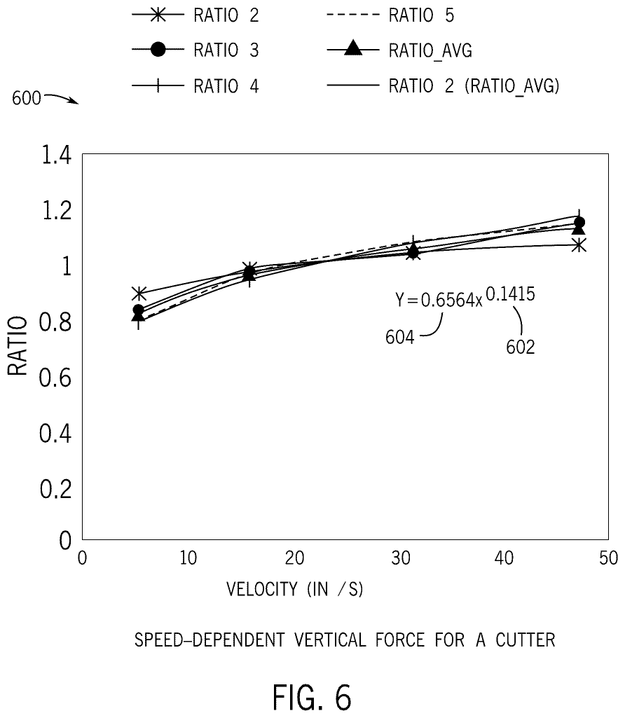

In some embodiments, the cutter model may model parameters affecting HFTOs. To that end, the cutter model may create models to simulate the effect of cutters on drilling operations. For example, FIG. 6 is a plot 600 of the speed-dependent vertical force for a cutter exhibiting the rate hardening effect of cutting forces, which may influence the presence of HFTOs. The hardening effect equation may be stated as follows:

$${F}_{v} = ( a ln v + b ) {F}_{v}^{0} \qquad ( 1 )$$

In the above equation, Fᵥ⁰ may be the normal vertical force, v is the speed of the cutter, a and b are coefficients, and Fᵥ is the final vertical force of the cutter at a given speed. As in FIG. 6, the cutter model may be configured to plot the hardening effect equation with the power law. Therefore, the cutter model may plot the cutter speed versus the ratio of the final vertical force over the normal vertical force to determine the coefficients a and b. For example, in FIG. 6, the coefficient 602 is determined to be 0.1415 and coefficient 604 is determined to be 0.6564. Therefore, the cutter model may use the coefficients 602 and 604 to calculate the speed-dependent vertical force for the cutter against the rock type across various speeds. In some embodiments, the cutter model may represent the expected bit torque based on the cutter lab test samples.

The control/data acquisition system 262 may employ the cutter model to output graphical representations, equations, 3D models, numerical values, and any other information relating to the effect of the cutter on drilling operations. The control/data acquisition system 262 may then store the outputs in a database or other storage medium and/or may transmit the outputs to a display.

At block 506, the control/data acquisition system 262 may receive bit lab test data for multiple drill bits. The drill bits may each include multiple cutters. A single drill bit may include multiple cutter types. The bit lab test data may be acquired based on laboratory tests. Each laboratory test may include testing the force of a drill bit against a rock sample at a number of different speeds using different types of cutters. Each laboratory test may be controlled with respect to one or more parameters, such as angle, force, speed, and the like. Each laboratory test may be repeated for each of the multiple drill bits across different rock types. In some embodiments, the laboratory test may measure the bit torque experienced while drilling.

With the foregoing in mind, the bit lab test data may include the data related to the laboratory tests and/or the interactions between the drill bit and the rock sample, including the drill bit configuration (e.g., placement of cutters, types of cutters included, the shape of the drill bit), the rock types, the controlled variables, and any measured values. The bit lab test data may further include the cutter lab test data.

At block 508, the control/data acquisition system 262 may generate a bit model based on the cutter model and the bit lab test data. Additionally, in some embodiments, the control/data acquisition system 262 may further train previously generated bit model based on additional bit lab test data to improve the bit model's accuracy.

The control/data acquisition system 262 may use the bit model to verify or adjust the outputs of the cutter model to fit and/or match the bit lab test data. For example, the control/data acquisition system 262 may compare the plots output by the cutter model to a plot created from the bit lab test data to verify the data of the bit model. In some embodiments, the control/data acquisition system 262 may use the bit model to adjust the equation(s) of the cutter model that are employed create the plots in response to determining the plots output by the cutter model do not match the plot corresponding to the bit lab test data. In embodiments where the drill bit includes multiple cutter types, the bit model may provide insight for comparing the cutter model for each cutter type to the bit lab test data.

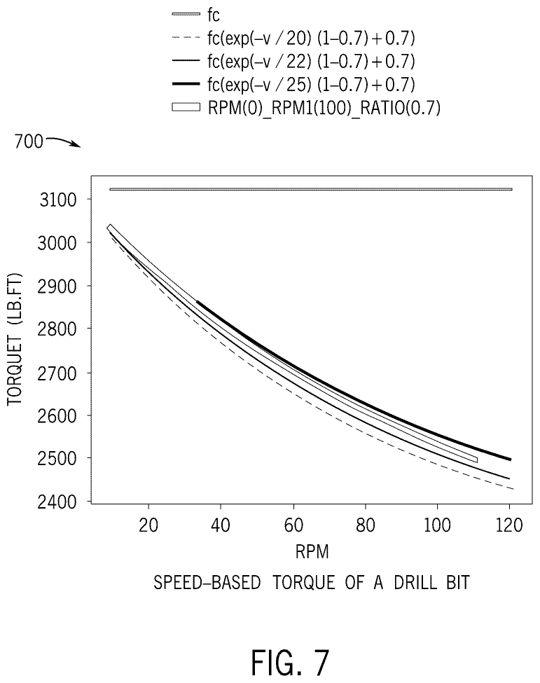

In some embodiments, the control/data acquisition system 262 may use the bit model to identify parameters affecting HFTOs. To that end, the control/data acquisition system 262 may use the bit model to simulate the effect of drill bits on drilling operations, such as the expected torque on the bit, on the drill string 225, and the like. As an example, FIG. 7 is a plot 700 of the velocity-based cutting force of a drill bit fitted to the bit torque per rotation per minute (RPM). The bit torque may be modeled using equation (2):

$$TOB = {TOB}_{0} [ exp ( - \frac{RPM - {RPM}_{0}}{{RPM}_{1} - {RPM}_{0}} ) ( 1 - {R}_{T} ) + {R}_{T} ] \qquad ( 2 )$$

In the above equation, TOB is the bit torque and RPM is the rotation per minute. The bit torque varies with the RPM. TOB₀, RPM₀, RPM₁, and R_{T} are model parameters. The model parameters may be determined by fitting modeling data to test data (e.g., the cutter lab test data, the bit lab test data). The cutting force model for a cutter may be modeled using equation (3):

$${F}_{c} = {f}_{c} ( exp ( - \frac{v}{{v}_{1}} ) * ( 1 - {r}_{T} ) + {r}_{T} ) \qquad ( 3 )$$

In the above equation, F_{c} is the cutter force and v is the cutting speed. The cutter force varies with the cutting speed. f_{c}, r_{T}, and v₁ are model parameters, which may be determined by fitting modeling data to test data (e.g., the cutter lab test data, the bit lab test data). The bit model includes a plot of the values as calculated using the cutter model and the corresponding values determined from the bit lab test data. The control/data acquisition system 262 may adjust equations used by the cutter model to cause the values of the cutter model to better fit the plot of the values from the bit lab test data. Thus, the bit model may be used to verify the cutter model's accuracy. For example, the cutter model may include an equation for the cutter force. The cutter model may calculate the bit torque from the cutter force and output a plot of the bit torque. The results of the bit lab test data may be plotted on the plot of the bit torque and the control/data acquisition system 262 may adjust the cutter model to better fit the plot of the bit torque according to the bit lab test data.

Similar to the cutter model, the bit model may be used to output graphical representations, equations, 3D models, numerical values, and any other information relating to the effect of the drill bit on drilling operations, and in particular on HFTOs. The control/data acquisition system 262 may store the outputs in the database or other storage medium and/or may transmit the outputs to the display.

In block 510, the control/data acquisition system 262 may receive field drilling log data for various drill bits and rock formations. The field drilling log data may include data received while drilling a particular formation with a particular drill bit. Thus, the field drilling log data may be collected during drilling operations. Alternatively, the field drilling log data may be collected as part of experimental or test operations. In some embodiments, the field drilling log data may include information related to the bit such as the configuration of the drill bit, the weight of the drill bit, the positions and number of mud ports, other parameters described above with respect to FIGS. 1 and 2. Additionally, the field drilling log data may include formation data relating to the geological characteristics of the formation drilled. For example, the formation data may include the tortuosity, damping coefficients, homogeneity or inhomogeneity, interbedded rock, inclusion rock, friction dependence on speed, rock type, and the like of the formation. The field drilling log data may further include additional factors affecting drilling, including temperature, heat transfer, stress, strain, mud properties, fluid dynamics, fluid properties, and the like.

At block 512, the control/data acquisition system 262 may simulate drilling dynamics for various drill bits and rock formations based on the bit model, the cutter model, the field drilling log data, or combination thereof. For example, in some embodiments, the control/data acquisition system 262 may simulate the drilling dynamics based on the bit model and the field drilling log data. In other embodiments, the control/data acquisition system 262 may simulate the drilling dynamics based on the cutter model and the field drilling log data. The control/data acquisition system 262 may use the field drilling log data to generate and/or train a drilling simulator to improve the drilling simulator's accuracy.

In various instances, one or more types of drilling dynamics (e.g., torsional oscillations across the drill string 225) may be simulated using the drilling simulator. For example, consider one or more of the IDEAS family of simulators (IDEAS: Integrated Dynamic Engineering Analysis System, SLB, Houston, Texas). As an example, the drilling simulator may be utilized to predict downhole behavior to deal with various drilling challenges such as HFTOs. Various aspects of simulation, including finite element analysis (FEA) simulation where an FEA mesh may be utilized to represent a modeled body such as a drill string 225. However, any suitable simulation technique may be employed to simulate the drilling dynamics.

The control/data acquisition system 262 may use the drilling simulator to account for physical phenomena such as phenomena related to one or more of temperature, heat transfer, stress, strain, fluid dynamics, fluid properties, rock physics, and the like. Additionally, the drilling simulator may use various operation factors to simulate the drilling dynamics. For example, the operation factors may include information as to trajectory, wellbore and/or borehole geometry, mud (drilling fluid), BHA configuration, and the like. Such drilling factors may be provided as inputs into the drilling simulator. In some embodiments, the drilling simulator may determine the drilling factors based on the bit lab test data, the field drilling log data, the physical phenomena, or any combination thereof. For example, the drilling simulator may determine the appropriate mud to be used based on the formation data of the field drilling log data.

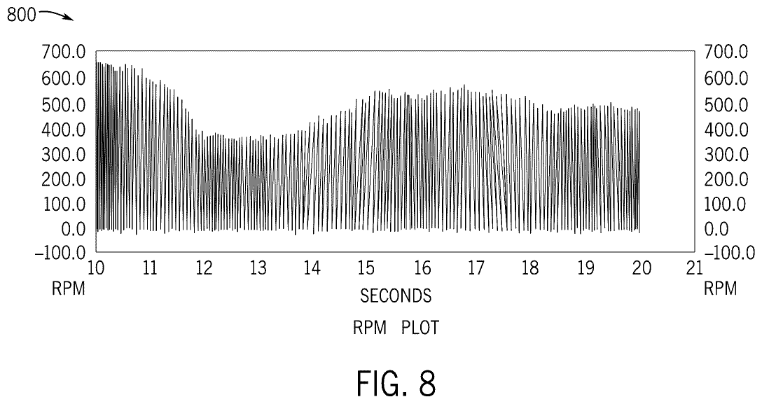

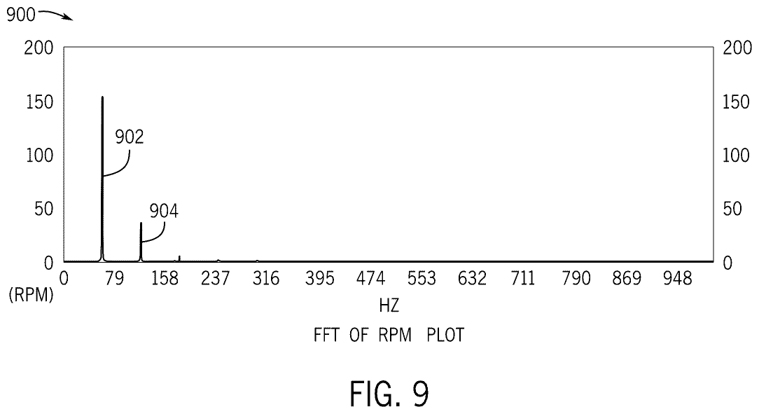

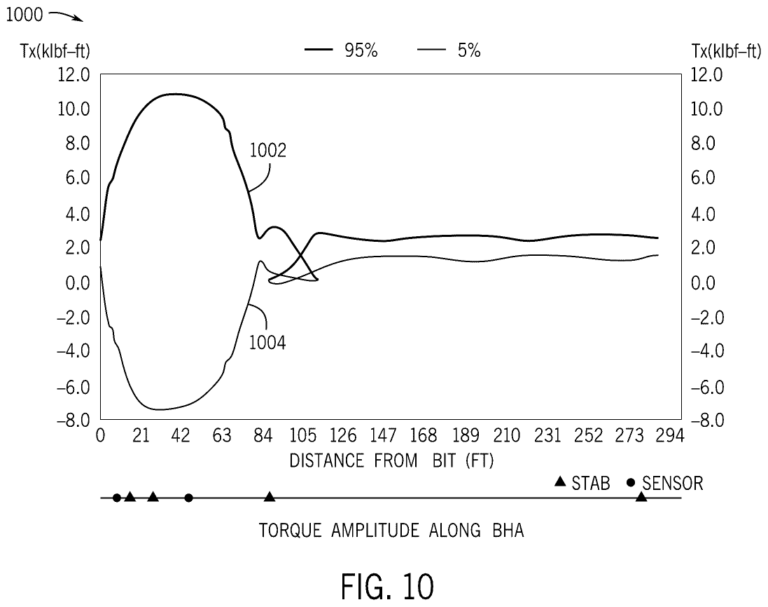

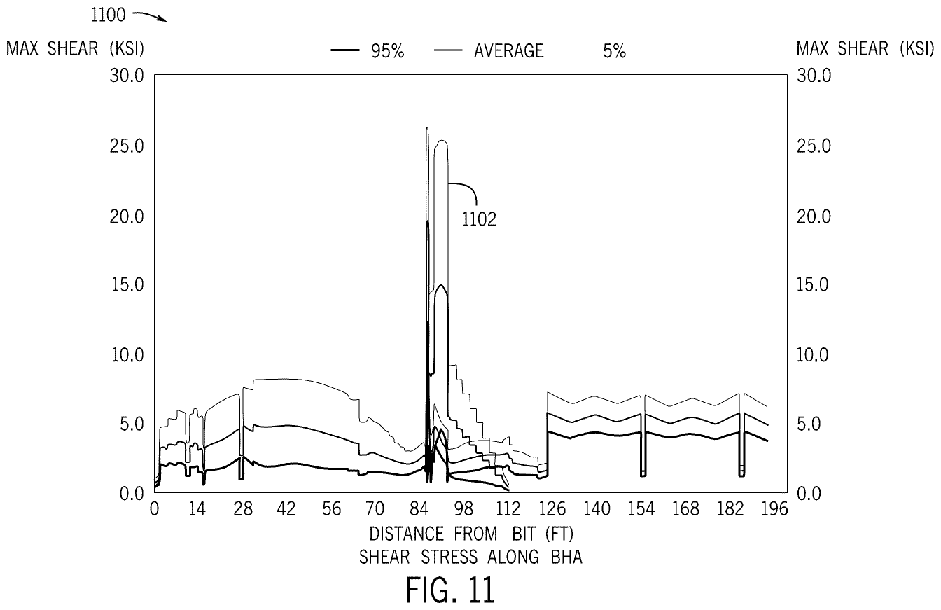

The control/data acquisition system 262 may use the drilling simulator to generate model outputs that include graphical representations, equations, 3D models, numerical values, and any other data relating to HFTOs based on the bit model, the cutter model, the field drilling log data, or any combination thereof. For example, FIG. 8 is an RPM plot 800 output by the drilling simulator based on the bit model and the field drilling log data. The RPM plot 800 illustrates the RPM of the drill bit over a period of time. The drilling simulator may further use the model outputs to simulate additional parameters affecting HFTOs. For example, FIG. 9 is a Fast Fourier Transform (FFT) 900 of the RPM plot of FIG. 8 output by the drilling simulator. The FFT 900 illustrates the frequency spectrum associated with the RPM of the drill bit. Because vibrations (e.g., HFTOs) may alter frequencies, peaks in the FFT 900 like peak 902 and peak 904 may indicate the presence of HFTOs in the drill string 225. As an additional example, FIG. 10 is a plot 1000 of the torque amplitude distribution along the BHA output by the drilling simulator. High ranges of torque such as ranges 1002 and 1004 may indicate the presence of HFTOs. Lastly, FIG. 11 is a plot 1100 of the shear stress along the BHA of FIG. 10 as output by the drilling simulator. A peak in the shear stress plot 1100 such as peak 1102 may indicate the presence of HFTOs. The control/data acquisition system 262 may record the likely presence of HFTOs in a particular simulation in a database and/or via a display in response to detecting a peak in the FFT, a high range of torques in the torque amplitude distribution plot, a peak in the shear stress plot, and the like.

In some embodiments, the control/data acquisition system 262 may perform blocks 514 and blocks 516 as pre-drilling operations. That is, after building the drilling simulator based on the data received and analysis performed at blocks 502-512, the control/data acquisition system 262 may, at block 514, use data related to a future drilling operation to identify a suitable bit design to use that may minimize or reduce the amount of HFTOs that may be experienced during the drilling operation.

With this in mind, at block 514, the control/data acquisition system 262 may receive the borehole data for a borehole to be drilled in a particular formation. The borehole data may include the formation data associated with the particular formation. The borehole data may further include operations factors such as trajectory and borehole geometry. For example, the borehole data may include the planned path for drilling through the formation. The planned path may include information regarding the rock type encountered during drilling, the amount of each rock type encountered during drilling, the angle of drilling across each rock type, and the like. Additionally, in some embodiments, the borehole data may include operations parameters, such as speed of the drill bit and weight on bit. In some embodiments, an operator may input the borehole data into the control/data acquisition system 262.

At block 516, the control/data acquisition system 262 may determine the drill bit design based on the simulated drilling dynamics and the borehole data. As such, the control/data acquisition system 262 may simulate the drilling dynamics for a number of drill bit designs based on the trained drilling simulator using the borehole data to determine the expected presence and extent of HFTOs in the drill string 225 during a drilling operation within the specified borehole. The drill bit design may be suitable for both completing drilling operations and for reducing the presence of HFTOs.

In some embodiments, the control/data acquisition system 262 may first analyze the borehole data to generate a list of cutter types and bit types less likely to result in the HFTOs based on the borehole data, the cutter model, the bit model, and the like. The control/data acquisition system 262 may conduct simulations for the cutter types and bit types on the list for the borehole data. For example, the control/data acquisition system 262 may determine a particular cutter interacts with each rock type of the borehole data such that minimal, reduced, or no HFTOs are produced based on the outputs of the cutter model. The control/data acquisition system 262 may then verify that a bit design including the particular cutter mitigates the HFTOs by simulating the drilling dynamics of the bit design across the rock types included in the borehole data. In some embodiments, the control/data acquisition system 262 may simulate bit designs that include multiple cutter types. In some embodiments, the operator may specify the cutter types and bit types to be simulated for the borehole data.

After the control/data acquisition system 262 has completed the simulations, the control/data acquisition system 262 may compare the outputs of each drilling simulation to determine the presence of HFTOs in the drill string 225 for each drill bit design during expected drilling operations. As such, the control/data acquisition system 262 may select one or more drill bit designs for the borehole data that result in fewer or no HFTOs as compared to other designs. The selected drill bit designs may be stored in the database or other storage and/or provide as outputs for a user to view via the display. In some embodiments, the control/data acquisition system 262 may output the drill bit designs resulting in HFTOs below a certain threshold, that both optimizes the performance of drilling operations and mitigates HFTOs, and the like.

In addition to employing the workflow 500 for selecting drill bit designs, the control/data acquisition system 262 may use the workflow 500 to adjust drilling operations in real time or based on feedback received from the drill string 225. For example, after simulating the drilling dynamics at block 512, the control/data acquisition system 262 may perform blocks 518, 520, and 522 during drilling operations to adjust drilling parameters while drilling. In some embodiments, after determining the drill bit design in block 516, the control/data acquisition system 262 may perform blocks 518, 520, and 522 during drilling operations employing the drill bit design to adjust drilling parameters while drilling.

For instance, at block 518, the control/data acquisition system 262 may receive drilling feedback data from the drill string 225, components on the drill string 225, and the like. The drilling feedback may include feedback received from sensors that collect information during drilling operations. The drilling feedback may include speed of drill bit, weight on bit, temperature, heat transfer, stress and/or strain on drill string 225, trajectory, wellbore and/or borehole geometry, mud (drilling fluid), BHA characteristics, drill bit characteristics, formation data, and the like. The drilling feedback may indicate the presence of HFTOs in the drill string 225. For example, the drilling feedback may include measurements of the torque across the drill string 225. In another example, the drilling feedback may include indications of a tool failure. In some embodiments, the drilling feedback data may be associated with drilling operations employing the drill bit design as determined in block 516.

At block 520, the control/data acquisition system 262 may determine updated drilling parameters based on the simulated drilling dynamics and the drilling feedback data. The control/data acquisition system 262 may update the drilling parameters in response to receiving drilling feedback indicating the presence of HFTOs above a certain threshold. In embodiments in which the drilling feedback is input by the operator, the control/data acquisition system 262 may automatically update the drilling parameters regardless of the presence of HFTOs. The drilling parameters may include the speed of the drill bit and the weight on bit being used in operations. The control/data acquisition system 262 may simulate the drilling dynamics of the drilling operations based on the drilling feedback data via the trained drilling simulator to determine a speed of the drill bit and/or weight on bit that mitigates the HFTOs.

The drilling simulator may simulate drilling with varying speeds and/or varying weight on bit. The drilling simulator may output information regarding the presence of HFTOs in the drill string 225 at each speed and weight on bit. The drilling simulator may analyze the information regarding the presence of HFTOs to determine the speed of drill bit, weight on bit, or other drilling parameters. The determined drilling parameters may mitigate HFTOs without excessive interruptions, delays, or inefficiencies in drilling operations. The control/data acquisition system 262 may determine the drilling parameters (e.g., the speed on drill bit, the weight on bit) according to the outputs of the drilling simulator. In some embodiments, the control/data acquisition system 262 may store the updated drilling parameters in the database.

As an example, the drilling simulator may indicate that decreasing the speed of the drill bit may decrease the HFTOs in the drill string 225 and/or that decreasing the weight on bit may decrease the HFTOs in the drill string 225. In such cases, the drilling simulator may determine that a decreased speed on the drill bit and/or a decreased weight on bit would mitigate HFTOs without excessively affecting drilling operations. The control/data acquisition system 262 may then determine an updated speed on drill bit and an updated weight on bit to use.

Additionally, the control/data acquisition system 262 may analyze the expected performance, integrity, wear, and effectiveness of the cutter and drill bit drilling through the rock formation at various speeds and weights on bit. As such, the control/data acquisition system 262 may determine updated drilling parameters to optimize the bit design's expected performance, integrity, and effectiveness and to reduce to the wear and the presence of HFTOs.

At block 522, the control/data acquisition system 262 may send the updated drilling parameters to the downhole tool. Thus, the control/data acquisition system 262 may adjust the operations of the downhole tool according to the updated parameters by sending the downhole tool instructions. For example, the control/data acquisition system 262 may send an instruction to the downhole tool to operate the drill bit at a slower speed. As another example, the control/data acquisition system 262 may send an instruction to the downhole tool to apply less weight on bit. The downhole tool may act according to the instruction. In some embodiments, the control/data acquisition system 262 may send the updated drilling parameters to a separate controller that may send the updated drilling parameters to the downhole tool.

Technical effects of the disclosed embodiments include a system and method for designing drill bits and controlling drilling operations to mitigate HFTOs. The system includes employing different models to determine a suitable design for a drill bit to perform respective drilling operations in a corresponding rock formation of the earth. By way of example, the system may employ a cutter, a bit model, and a drilling dynamics simulator at different stages to determine the amount of HFTOs caused by a particular drill bit drilling through the corresponding rock formation. By modeling and/or simulating the drill string's interactions with the rock formation at the cutter level, bit level, and drill string level, the system produces a more accurate prediction of the effects of the drill bit design on the HFTOs in the drill string. Thus, the system may determine a drill bit design resulting in the least amount of HFTOs in the drill string during pre-drilling operations, thereby ensuring efficient use of resources and increased lifespan of the downhole tool. After determining the drill bit design, in some embodiments, the system may determine and adjust drilling parameters of a drill system during drilling operations to reduce the presence of HFTOs, thereby reducing the stress and/or strain on the drill string. By mitigating HFTOs, the system reduces wear on the drill string; increases the performance, integrity, and effectiveness of the drill bit; and increases the efficiency of drilling operations by preventing critical failure of the drill string.

The foregoing description, for purpose of explanation, has been described with reference to specific embodiments. However, the illustrative discussions above are not intended to be exhaustive or to limit the disclosure to the precise forms disclosed. Many modifications and variations are possible in view of the above teachings. Moreover, the order in which the elements of the methods described herein are illustrated and described may be re-arranged, and/or two or more elements may occur simultaneously. The embodiments were chosen and described in order to best explain the principals of the disclosure and its practical applications, to thereby enable others skilled in the art to best utilize the disclosure and various embodiments with various modifications as are suited to the particular use contemplated.

Finally, the techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

1. A method, comprising:
receiving, via a processing system, cutter lab test data associated with a plurality of cutter types;
generating, via the processing system, a first model based on the cutter lab test data, wherein the first model is representative of one or more effects to one or more rock types provided by using one or more cutter types of the plurality of cutter types;
receiving, via the processing system, bit lab test data associated with a first plurality of drill bits;
generating, via the processing system, a second model based on the first model and the bit lab test data, wherein the second model is representative of one or more additional effects to the one or more rock types provided by using one or more drill bits of the first plurality of drill bits deployed in a bottom hole assembly with the one or more cutter types;
receiving, via the processing system, drilling log data associated with a second plurality of drill bits comprising the one or more drill bits;
simulating, via the processing system, drilling dynamics for the first plurality of drill bits and the second plurality of drill bits based on:
the first model and the drilling log data; or
the second model and the drilling log data;
receiving, via the processing system, borehole data associated with a borehole;
determining, via the processing system, a bit design for use in the borehole based on the simulated drilling dynamics and the borehole data;
receiving drilling feedback data associated with drilling within the borehole using the bit design;
determining one or more drilling parameters for the bottom hole assembly based on the simulated drilling dynamics and the drilling feedback data, wherein the one or more drilling parameters comprise a speed of a drill bit, a weight on bit, or both; and
sending the one or more drilling parameters to a control system configured to adjust one or more operations of a drilling tool associated with the bottom hole assembly based on the one or more drilling parameters.

2. The method of claim 1, wherein the cutter lab test data comprises one or more forces associated with each of the plurality of cutter types being applied to each of the one or more rock types.

3. The method of claim 1, wherein the bit lab test data comprises one or more forces associated with each of the first plurality of drill bits being applied to each of the one or more rock types.

4. The method of claim 1, wherein the drilling log data comprises one or more effects associated with each of the second plurality of drill bits being applied to one or more rock formations.

5. The method of claim 1, wherein drilling dynamics comprises one or more torsional oscillations across a drill string associated with the bottom hole assembly.

6. The method of claim 1, wherein determining the bit design for use in the borehole based on the simulated drilling dynamics and the borehole data comprises:
simulating a plurality of torsional oscillations across a drill string associated with the bottom hole assembly using a plurality of bit designs, wherein each of the plurality of bit designs comprises one of the first plurality of drill bits or one of the second plurality of drill bits;
comparing each of the plurality of torsional oscillations for each of the plurality of bit designs; and
selecting the bit design causing a least amount of torsional oscillations based on the plurality of torsional oscillations.

7. (canceled)

8. A non-transitory computer-readable medium comprising computer-executable instructions that, when executed, cause a processing system to perform operations comprising:
receiving cutter lab test data associated with a plurality of cutter types;
generating a first model based on the cutter lab test data, wherein the first model is representative of one or more effects to one or more rock types provided by using one or more cutter types of the plurality of cutter types;
receiving bit lab test data associated with a first plurality of drill bits;
generating a second model based on the first model and the bit lab test data, wherein the second model is representative of one or more additional effects to the one or more rock types provided by using one or more drill bits of the first plurality of drill bits deployed in a bottom hole assembly with the one or more cutter types;
receiving drilling log data associated with a second plurality of drill bits comprising the one or more drill bits;
simulating drilling dynamics for the first plurality of drill bits and the second plurality of drill bits based on:
the first model and the drilling log data; or
the second model and the drilling log data;
receiving borehole data associated with a borehole;
determining a bit design for use in the borehole based on the simulated drilling dynamics and the borehole data;
receiving drilling feedback data associated with drilling within the borehole using the bit design;
determining one or more drilling parameters for the bottom hole assembly based on the simulated drilling dynamics and the drilling feedback data, wherein the one or more drilling parameters comprise a speed of a drill bit, a weight on bit, or both; and
sending the one or more drilling parameters to a control system configured to adjust one or more operations of a drilling tool associated with the bottom hole assembly based on the one or more drilling parameters.

9. The non-transitory computer-readable medium of claim 8, wherein the cutter lab test data comprises one or more forces associated with each of the plurality of cutter types being applied to each of the one or more rock types.

10. The non-transitory computer-readable medium of claim 8, wherein the bit lab test data comprises one or more forces associated with each of the first plurality of drill bits being applied to each of the one or more rock types.

11. The non-transitory computer-readable medium of claim 8, wherein the first model outputs an equation describing a speed-dependent force of a cutter of the plurality of cutters types.

12. The non-transitory computer-readable medium of claim 11, wherein generating the second model based on the first model and the bit lab test data comprises adjusting the equation of the first model to fit a plot of the bit lab test data.

13. The non-transitory computer-readable medium of claim 8, wherein the processing system performing operations comprising determining the bit design based on the simulated drilling dynamics and the borehole data comprises:
simulating a plurality of torsional oscillations across a drill string associated with the bottom hole assembly using a plurality of bit designs, wherein each of the plurality of bit designs comprises one of the first plurality of drill bits or one of the second plurality of drill bits;
comparing each of the plurality of torsional oscillations for each of the plurality of bit designs; and
selecting the bit design causing a least amount of torsional oscillations based on the plurality of torsional oscillations.

14. (canceled)

15. A system, comprising:
a storage component comprising cutter lab test data and bit lab test data, wherein the cutter lab test data comprises one or more forces associated with each of a plurality of cutter types being applied to each of one or more rock types, and wherein the bit lab test data comprises one or more forces associated with each of a first plurality of drill bits being applied to each of the one or more rock types;
a processing system configured to:
receive the cutter lab test data associated with the plurality of cutter types;
generate a first model based on the cutter lab test data, wherein the first model is representative of one or more effects to one or more rock types provided by using one or more cutter types of the plurality of cutter types;
receive the bit lab test data associated with the first plurality of drill bits;
generate a second model based on the first model and the bit lab test data, wherein the second model is representative of one or more additional effects to the one or more rock types provided by using one or more drill bits of the first plurality of drill bits deployed in a bottom hole assembly with the one or more cutter types;
receive drilling log data associated with a second plurality of drill bits comprising the one or more drill bits;
simulate drilling dynamics for the first plurality of drill bits and the second plurality of drill bits based on:
the first model and the drilling log data; or
the second model and the drilling log data;
receive borehole data associated with a borehole;
determine a bit design for use in the borehole based on the simulated drilling dynamics and the borehole data;
receiving drilling feedback data associated with drilling within the borehole using the bit design;
determining one or more drilling parameters for the bottom hole assembly based on the simulated drilling dynamics and the drilling feedback data, wherein the one or more drilling parameters comprise a speed of a drill bit, a weight on bit, or both; and
sending the one or more drilling parameters to a control system configured to adjust one or more operations of a drilling tool associated with the bottom hole assembly based on the one or more drilling parameters.

16. The system of claim 15, wherein the drilling log data comprises one or more effects associated with each of the second plurality of drill bits being applied to one or more rock formations.

17. The system of claim 15, wherein drilling dynamics comprises one or more torsional oscillations across a drill string associated with the bottom hole assembly.

18. The system of claim 15, wherein determining the bit design for use in the borehole based on the simulated drilling dynamics and the borehole data comprises determining the bit design results in one or more torsional oscillations below a certain threshold.

19-20. (canceled)

21. The method of claim 1, wherein determining the one or more drilling parameters for the bottom hole assembly based on the simulated drilling dynamics and the drilling feedback data comprises determining one or more drilling parameters that reduce one or more torsional oscillations below a certain threshold.

22. The non-transitory computer-readable medium of claim 8, wherein determining the one or more drilling parameters for the bottom hole assembly based on the simulated drilling dynamics and the drilling feedback data comprises determining one or more drilling parameters that reduce one or more torsional oscillations below a certain threshold.

23. The system of claim 15, wherein determining the one or more drilling parameters for the bottom hole assembly based on the simulated drilling dynamics and the drilling feedback data comprises determining one or more drilling parameters that reduce one or more torsional oscillations below a certain threshold.
